(19) United States
(12) Patent Application Publication
(10) Pub. No.: US 2021/0167019 A1
(43) Pub. Date: Jun. 3, 2021

(54) METAL INTERCONNECTS, DEVICES, AND METHODS

(71) Applicant: Intel Corporation, Santa Clara, CA (US)

(72) Inventors: Daniel Zierath, Portland, OR (US); Srijit Mukherjee, Portland, OR (US); Jason Farmer, Hillsboro, OR (US); Chandan Ganpule, Portland, OR (US); Julia Lin, Portland, OR (US)

(73) Assignee: Intel Corporation, Santa Clara, CA (US)

(21) Appl. No.: 16/636,315

(22) PCT Filed: Sep. 1, 2017
(86) PCT No.: PCT/US2017/049938

§ 371 Date: Feb. 3, 2020

(51) Int. Cl. H01L 23/532; H01L 21/768

(52) U.S. Cl. CPC H01L 23/53209; H01L 21/76807; H01L 21/7684; H01L 21/76846

(57) ABSTRACT

Provided herein are metal interconnects that may include a cobalt alloy, a nickel alloy, or nickel. Also provided herein are methods of making metal interconnects. The metal interconnects may include a barrier and/or adhesion layer, a seed layer, a fill material, a cap, or a combination thereof, and at least one of the barrier and/or adhesion layer, the seed layer, the fill material, or the cap may include a cobalt alloy, a nickel alloy, nickel, or a combination thereof.

### BACKGROUND

Integrated circuit (IC) devices typically include circuit elements such as transistors, capacitors, and resistors formed within or on a semiconductor substrate. Interconnect structures are used to electrically couple or connect the discrete circuit elements into functional circuits.

Interconnect structures typically include copper or tungsten. Copper and tungsten, however, cause one or more difficulties regarding scaling up the size of interconnects. For example, void-free fabrication of interconnects is difficult when copper or tungsten is used. When copper is used, a barrier/adhesion layer and a seed layer are usually required, and processing of copper interconnects typically relies on a field suppression/super-fill approach. When tungsten is used, a barrier/adhesion layer and a nucleation layer are usually required. A nucleation layer tends to have a relatively high resistance, and processing of tungsten typically relies on chemical vapor deposition (CVD) or a conformal process, which may cause seams, keyholes, or a combination thereof in the interconnect structure.

Moreover, the resistivity of copper interconnect structures may increase as the dimensions of the structure are decreased (as the feature is scaled), and the current density requirement can increase when the structure geometry is scaled, which can worsen its electromigration performance.

Due to one or more of the disadvantages associated with copper or tungsten, cobalt has been tested as a replacement material in interconnects. Cobalt generally has [1] a lower resistivity than tungsten nucleation layers and Ta barriers, [2] a higher melting point than copper, which results in a high activation energy for diffusion, thereby improving reliability/electromigration, [3] the ability to recrystalize upon annealing, thereby enabling reflow for better gap fill, [4] better adhesion strength to oxide than copper, or [5] a combination thereof.

Nevertheless, the use of cobalt as a metal interconnect material may be disadvantageous due to the fact that cobalt interconnects are susceptible to corrosion, especially at a pH less than 9. Employing solutions having a higher pH, however, typically is not practical. Other disadvantages that may be associated with cobalt-based interconnect structures include stress-induced voiding.

There remains a need for interconnect materials that are less susceptible to corrosion than cobalt, including interconnect materials that are less susceptible to corrosion than cobalt while having or maintaining low resistance, reliability, or a combination thereof. There also remains a need for interconnect materials that are less susceptible to at least one of stress-induced voiding or electromigration.

### BRIEF DESCRIPTION OF THE DRAWINGS

FIG. 1A is a cross-sectional side view of one embodiment of a dual damascene structure.

FIG. 1B is a cross-sectional side view of an embodiment of a barrier and/or adhesion layer deposited in the dual damascene structure of FIG. 1A.

FIG. 1C is a cross-sectional side view of an embodiment of a seed layer deposited in the dual damascene structure of FIG. 1B.

FIG. 1D is a cross-sectional side view of an embodiment of a fill material deposited in the dual damascene structure of FIG. 1C.

FIG. 1E is a cross-sectional side view of an embodiment of an overburden deposited on the dual damascene structure of FIG. 1D.

FIG. 1F is a cross-sectional side of view of the embodiment of FIG. 1E after annealing and polishing.

FIG. 2 is a cross-sectional side view of an embodiment of a metal interconnect.

FIG. 3 is a cross-sectional side view of an embodiment of a metal interconnect that includes an embodiment of an overburden.

FIG. 4 is a cross-sectional side view of an embodiment of a metal interconnect that includes an embodiment of a cap.

FIG. 5 is a flow chart depicting one embodiment of a method of forming a metal interconnect.

FIG. 6 depicts an embodiment of a computing device.

### DETAILED DESCRIPTION

Provided herein are metal interconnects including a cobalt alloy, nickel, a nickel alloy, or a combination thereof that may be less susceptible to corrosion than cobalt. In embodiments, the metal interconnects provided herein are less susceptible to corrosion than cobalt, while having or maintaining low resistance, reliability, or a combination thereof. Additionally or alternatively, the metal interconnects provided herein may be less susceptible to at least one of stress-induced voiding or electromigration than cobalt. In particular embodiments, the metal alloys of the interconnects provided herein have a higher melting point than cobalt. Not wishing to be bound by any particular theory, it is believed that the higher melting point may impart embodiments of the metal alloys herein with a higher activation energy than cobalt, thereby reducing interdiffusion. The reduction of interdiffusion may result in improved stress-induced voiding, electromigration, or a combination thereof. In some embodiments, the metal alloys provided herein are less susceptible to corrosion and voiding migration than cobalt, which may result in an improved end-of-line yield.

Embodiments described herein are directed to metal interconnects including a cobalt alloy, nickel, a nickel alloy, or a combination thereof, and methods of fabricating metal interconnects including a cobalt alloy, nickel, a nickel alloy, or a combination thereof. It should be noted that in various embodiments, description is made with reference to figures. However, certain embodiments may be practiced without one or more of these specific details, or in combination with other known methods and configurations. In the following description, numerous specific details are set forth, such as specific configurations, dimensions, processes, etc., in order to provide a thorough understanding of the disclosure. In other instances, well-known semiconductor processes and manufacturing techniques have not been described in particular detail in order to avoid unnecessarily obscuring the present disclosure. Reference throughout this specification to “one embodiment,” “an embodiment,” or the like means that a particular feature, structure, configuration, or characteristic described in connection with the embodiment is included in at least one embodiment of the disclosure. Therefore, the appearances of the phrase “in one embodiment,” “an embodiment,” or the like in various places throughout this specification are not necessarily referring to the same embodiment of the disclosure. Furthermore, the particular features, structures, configurations, or characteristics may be combined in any suitable manner in one or more embodiments.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

### Metal Interconnects

In embodiments, the metal interconnects provided herein include a compound according to formula (I) or formula (II)

CoₐQ_{q}Z_{z} (formula (I)),

Ni_{d}XₑY_{f} (formula (II));

wherein a is a weight percentage of about 50% to about 99.99% based on the total weight of the compound of formula (I); q is a weight percentage of about 0.01% to about 50% based on the total weight of the compound of formula (I); z is a weight percentage of 0% to about 49.9% based on the total weight of the compound of formula (I); Q, when z is 0%, is selected from Ni, Al, Mn, Si, Cr, V, Mo, Zr, Nb, Ta, or W; Q, when z is not 0%, is selected from Ni, Al, Mn, Si, Cr, V, Zr, Nb, or Ta; Z is selected from Mo or W; d is a weight percentage of about 50% to 100% based on the total weight of the compound of formula (II); e is a weight percentage of 0% to about 50% based on the total weight of the compound of formula (II); f is a weight percentage of 0% to about 49.99% based on the total weight of the compound of formula (II); X, when f is 0%, is selected from Co, Al, Mn, Si, Cr, V, Mo, Zr, Nb, Ta, or W; X, when f is not 0%, is selected from Co, Al, Mn, Si, Cr, V, Zr, Nb, or Ta,; and Y is selected from Mo or W.

In embodiments, the metal interconnects provided herein include a compound according to formula (I) or formula (II)

CoₐQ_{q}Z_{z} (formula (I)),

Ni_{d}XₑY_{f} (formula (II)); and

two or more of the following materials or layers: a barrier and/or adhesion layer, a seed layer, a fill material, or a cap; wherein a is a weight percentage of about 50% to about 99.99% based on the total weight of the compound of formula (I); q is a weight percentage of about 0.01% to about 50% based on the total weight of the compound of formula (I); z is a weight percentage of 0% to about 49.9% based on the total weight of the compound of formula (I); Q, when z is 0%, is selected from Ni, Al, Mn, Si, Cr, V, Mo, Zr, Nb, Ta, or W; Q, when z is not 0%, is selected from Ni, Al, Mn, Si, Cr, V, Zr, Nb, or Ta; Z is selected from Mo or W; d is a weight percentage of about 50% to 100% based on the total weight of the compound of formula (II); e is a weight percentage of 0% to about 50% based on the total weight of the compound of formula (II); f is a weight percentage of 0% to about 49.99% based on the total weight of the compound of formula (II); X, when f is 0%, is selected from Co, Al, Mn, Si, Cr, V, Mo, Zr, Nb, Ta, or W; X, when f is not 0%, is selected from Co, Al, Mn, Si, Cr, V, Zr, Nb, or Ta,; and Y is selected from Mo or W.

In embodiments, the metal interconnects include a compound according to formula (I), wherein Q is Ni; a is about 80% to about 95%; q is about 5% to about 20%; and z is 0%. In some embodiments, the metal interconnects include a compound according to formula (I), wherein Q is Ni; a is about 84% to about 88%; q is about 12% to about 16%; and z is 0%. In further embodiments, the metal interconnects include a compound according to formula (I), wherein Q is Ni; a is about 86%; q is about 14%; and z is 0%. In still further embodiments, the metal interconnects include a compound according to formula (I), wherein Q is Ni; a is about 96% to about 99%; q is about 1% to about 4%; and z is 0%. In additional embodiments, the metal interconnects include a compound according to formula (I), wherein Q is Ni; a is about 96% to about 98%; q is about 2% to about 4%; and z is 0%. In particular embodiments, the metal interconnects include a compound according to formula (I), wherein Q is Ni; a is about 97%; q is about 3%; and z is 0%. In certain embodiments, the metal interconnects include a compound according to formula (I), wherein Q is Si, and z is 0%.

In embodiments, the metal interconnects include a compound according to formula (II), wherein e and f are 0%.

In embodiments, the metal interconnects include a compound according to formula (II), wherein d is about 90% to about 92%, f is 0%, X is selected from V or W, and e is about 8% to about 10%. In another embodiment, the metal interconnects include a compound according to formula (II), wherein d is about 80% to about 84%, e is about 8% to about 10%, X is V, f is about 8% to about 10%, and Y is W.

In embodiments, the metal interconnects include a compound according to formula (I) or a compound according to formula (II) that includes at least one of Mo or W, wherein the Mo or W are independently present at a weight percentage of about 0.01% to about 1%, based on the total weight of the compound according to formula (I) or the compound according to formula (II), respectively.

Not wishing to be bound by any particular theory, it is believed that the inclusion of Mo or W in a compound of formula (I) and/or formula (II) can lower the bulk resistivity, impart a melting point greater than the melting point of cobalt or nickel, or a combination thereof, thereby possibly improving performance, increasing the activation energy, reducing the interdiffusion, or a combination thereof.

Not wishing to be bound by any particular theory, it is believed that, due to their relatively high affinity for forming metal oxide bonds, the inclusion of Al, Mn, Si, Cr, V, Ta, or Nb in a compound of formula (I) and/or formula (II) may passivate a cobalt or nickel surface, thereby preventing or reducing the likelihood of corrosion. Al, Mn, Si, and Cr are believed to be fast diffusers in metal, form very stable metal oxides, or a combination thereof. Al₂O₃, Cr₂O₃, SiO₂, MnO₂, and MnO have negative heats of formation that are about 5 to about 6 times greater than that of CoO.

Not wishing to be bound by any particular theory, it is believed that the inclusion of

Cr, Ta, Nb, or V in a compound of formula (I) and/or formula (II) can impart a melting point greater than the melting point of cobalt and/or nickel, which may increase activation energy and/or reduce the interdiffusion, thereby improving stress-induced voiding and electromigration.

Not wishing to be bound by any particular theory, it is believed that Pourbaix diagrams of Cr suggest a wider pH window for a passive metal-oxide layer formation, compared to Co. At a neutral pH, Cr may form Cr₂O₃, which can be a very stable oxide.

In one embodiment, the metal interconnects provided herein include a compound according to formula (I). In another embodiment, the metal interconnects provided herein include a compound according to formula (II). In a further embodiment, the metal interconnects provided herein include a compound according to formula (I) and a compound according to formula (II).

In embodiments, the metal interconnects provided herein include a compound according to formula (I), and the compound according to formula (I) is present in at least one of the barrier and/or adhesion layer, the seed layer, the fill material, or the cap. In other embodiments, the metal interconnects provided herein include a compound according to formula (II), and the compound according to formula (II) is present in at least one of the barrier and/or adhesion layer, the seed layer, the fill material, or the cap. For example, a compound of formula (I) or a compound of formula (II) may be present in [1] a barrier and/or adhesion layer, [2] a seed layer, [3] a fill material, [4] a cap, [5] a barrier and/or adhesion layer and a seed layer, [6] a barrier and/or adhesion layer and a fill material, [7] a seed layer and a fill material, [8] a fill material and a cap, [9] a barrier and/or adhesion layer, a fill material, a seed layer, and a cap, etc.

As used herein, the phrase “is present in at least one of the barrier and/or adhesion layer, the seed layer, the fill material, or the cap” describes a compound of formula (I) and/or formula (II) that is present in at least one of a barrier and/or adhesion layer, a seed layer, a fill material, or a cap prior to, during, or after the barrier and/or adhesion layer, the seed layer, the fill material, and the cap is deposited in a damascene or dual damascene structure. For example, a compound of formula (I) and/or (II) may be present in a seed layer before the seed layer is deposited in a damascene or dual damascene structure. As a further example, a compound of formula (I) and/or (II) may not be present in a seed layer prior to or during the depositing of the seed layer in a damascene or dual damascene structure, but a compound of formula (I) and/or (II) may be present in the seed layer after further processing, such as annealing, is performed. In each of these examples, the metal interconnect includes a seed layer in which a compound of formula (I) and/or formula (II) is present.

As used herein, the phrase “is present in” should not be construed as defining the composition of a barrier and/or adhesion layer, a seed layer, a fill material, a the cap. For example, in one embodiment, a compound of formula (I) “is present in” a seed layer, and the seed layer may include [1] only the compound of formula (I), or [2] the compound of formula (I) and at least one other component.

In embodiments, the metal interconnects provided herein include a compound according to formula (I) and a compound according to formula (II), and the compounds according to formula (I) and formula (II) independently are present in at least one of the barrier and/or adhesion layer, the seed layer, the fill material, or the cap. The compound according to formula (I) and the compound according to formula (II) may be present in one or more of the same layers or materials, one or more different layer or materials, or a combination thereof. For example, a compound according to formula (I) may be present in a seed layer, and a compound according to formula (II) may be present in a fill material. As a further example, a compound according to formula (I) and a compound according to formula (II) may be present in a seed layer. As another example, a compound according to formula (I) may be present in a seed layer and a fill material, and a compound according to formula (II) may be present in the fill material and a barrier and/or adhesion layer.

### Methods of Forming Metal Interconnects

Methods of forming metal interconnects including at least one compound according to formula (I), at least one compound according to formula (II), or a combination thereof are provided. In embodiments, the methods of forming metal interconnects include providing a damascene or a dual damascene structure; depositing a barrier and/or adhesion layer on the damascene or the dual damascene structure; depositing a seed layer on the barrier and/or adhesion layer; depositing a fill material in the damascene or dual damascene structure; and depositing (i) an over burden, or (ii) a cap on the fill material. At least one of the barrier and/or adhesion layer, the seed layer, the fill material, the over burden, or the cap may include at least one compound according to formula (I), at least one compound according to formula (II), or a combination thereof. The methods provided herein also may include one or more additional features, such as annealing the metal interconnect, polishing the metal interconnect, removing one or more portions of the layer(s) and/or material(s) deposited outside of a damascene or dual damascene structure, or combination thereof.

When the methods provided herein include depositing an over burden, the methods may also include [1] annealing the metal interconnect, [2] polishing the over burden, or [3] annealing the metal interconnect and polishing the over burden. The polishing may be achieved by any known technique, such as chemical mechanical planarization (CMP).

When the methods provided herein include depositing a cap, the methods may also include removing at least a portion of the barrier and/or adhesion layer, the fill material, the seed layer, or a combination thereof deposited outside of the damascene or the dual damascene structure. The removing of at least a portion of the barrier and/or adhesion layer, the fill material, the seed layer, or a combination thereof may be performed prior to depositing a cap, and achieved by any known techniques. In one embodiment, the removing includes CMP.

### Damascene or Dual Damascene Structure

The damascene and dual damascene structure of the methods provided herein may include any known structures. In embodiments, the dual damascene structure includes a dielectric layer deposited on a substrate; and an opening in the dielectric layer, the opening having a lower portion and an upper portion, wherein the upper portion is wider than the lower portion. In further embodiments, the dual damascene structure includes a dielectric layer deposited on a substrate; and an opening in the dielectric layer that exposes a conductive region of the substrate, the opening having a lower portion and an upper portion, wherein the upper portion is wider than the lower portion.

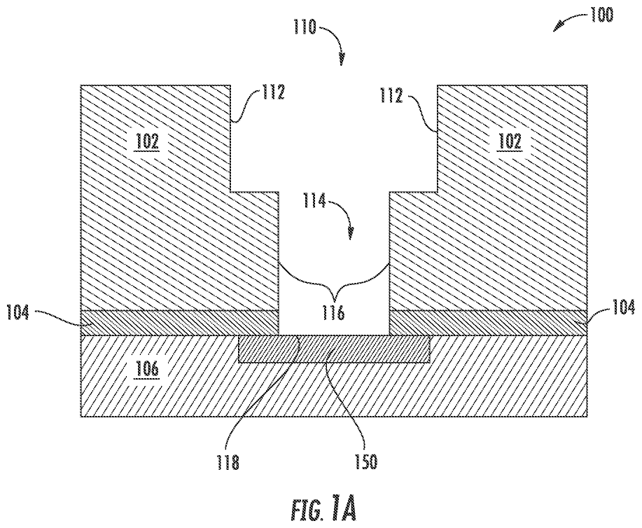

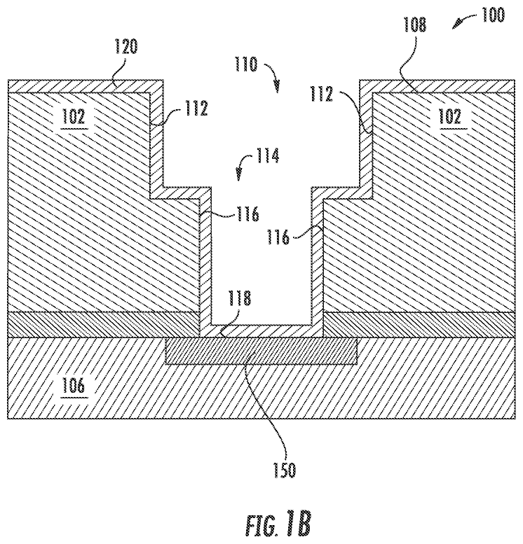

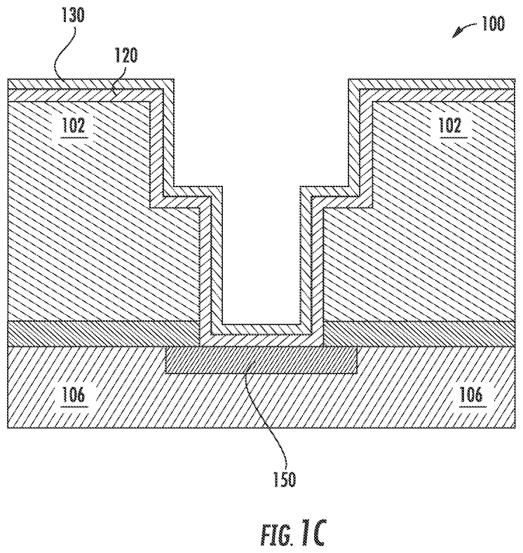

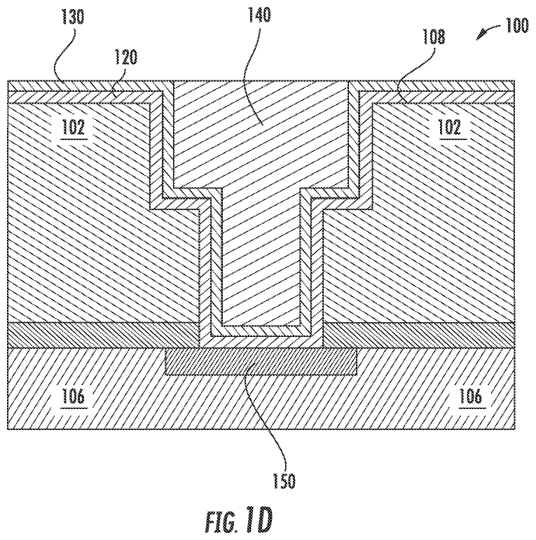

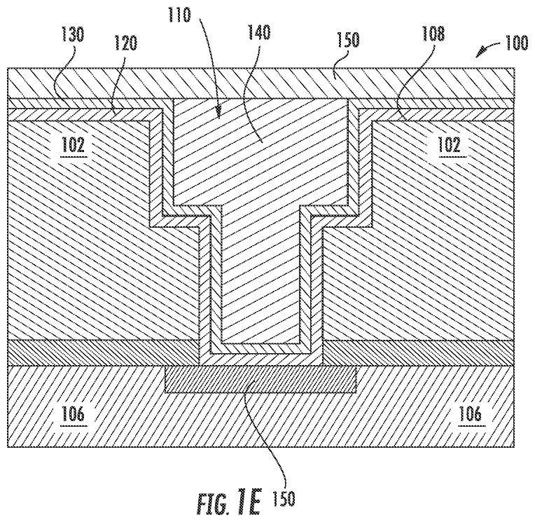

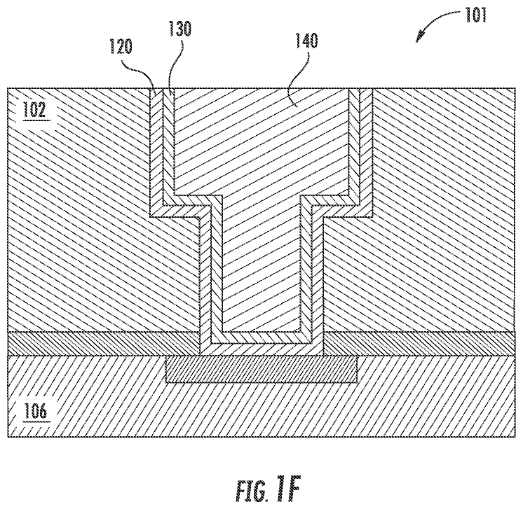

One embodiment of a dual damascene structure 100 is depicted at FIG. 1A. FIG. 1A depicts a substrate 106 with top surface 118 that may be used as a substrate onto which an interconnect may be formed. The substrate 106 can include any portion of a partially fabricated integrated circuit (IC) on which a metal interconnect may be fabricated. For example, the substrate 106 may include, or have formed thereon, active and passive devices. As depicted at FIG. 1A, a conductive region 150 is included in the substrate 106, onto which an interconnect may be formed. The substrate 106 may be processed through front end of line (FEOL), and the conductive region 150 may be a diffusion region formed in a crystalline semiconductor substrate or layer. For example, the conductive region may be a source or drain region of a transistor. The conductive region 150 may be an underlying metal line in a back end of line (BEOL) metallization structure. Although embodiments of a dual damascene structure may be ideally suited for fabricating semiconductor integrated circuits, including, but not limited to, microprocessors, memories, charge-coupled devices (CCDs), system on chip (SoC) ICs, or baseband processors, other applications can also include microelectronic machines, MEMS, lasers, optical devices, packaging layers, etc. Embodiments of the dual damascene structure also may be used to fabricate individual semiconductor devices, including, but not limited to, a gate electrode of a metal oxide semiconductor (MOS) transistor.

The dual damascene structure 100 depicted at FIG. 1A includes a dielectric layer 102 formed above the substrate 106. The dielectric layer 102 may include any suitable dielectric or insulating material, such as silicon dioxide, SiOF, carbon-doped oxide, a glass or polymer material. The opening in the dielectric layer 102 exposes the conductive region 150, to which contact by an interconnect is ultimately made, and the opening includes a lower opening 114 with sidewalls 116 and an upper opening 110 with sidewalls 112. Although two openings are depicted, it is to be appreciated that a single opening may instead be formed in the dielectric layer 102, as is used, for example, in a single damascene approach where only a line or a via, but not both, is fabricated in a single operation. The opening or openings may be fabricated in the dielectric layer 102 by known lithography and etch processing techniques typically used in damascene and dual damascene type fabrication. Although only a single dielectric layer 102 is depicted, multiple layers of the same or differing dielectric materials may instead be used. For example, a first dielectric layer may have the opening 114 therein, and a second dielectric layer may have the opening 110 therein. In the embodiment depicted at FIG. 1A, the dielectric layer 102 is on an etch stop layer 104 deposited on the substrate 106. The etch stop layer 104 may include any suitable material, such as silicon nitride, silicon oxynitride, or a combination thereof.

Embodiments of the methods provided herein include “depositing” a layer or material in a damascene or dual damascene structure and/or on another layer or material. The “depositing” may be achieved by any known techniques that may be appropriate for a particular layer or material, including, but not limited to, chemical vapor deposition (CVD), atomic layer deposition (ALD), physical vapor deposition (PVD), electroplating, electroless plating, one or more other suitable processes that deposit conformal thin films, or a combination thereof.

Deposition recipes of thin films using processes such as CVD, ALD, and PVD may vary depending on the desired process time, thickness, and quality of conformity. For example, utilizing CVD to deposit a seed layer may create a conformal thin film layer more quickly than it would take an ALD process to deposit the same layer; however, the quality of the thin film deposited by the CVD process may be lower than the quality of the thin film deposited by the ALD process. A PVD process may be performed with an increased distance between the receiving substrate and the corresponding sputter target to form a highly conformal thin film.

Adhesion and/or Barrier Layer

The adhesion/barrier layers herein may include Ta, TaN, TiN, WN, or a combination thereof. In one embodiment, the adhesion/barrier layer is a tantalum nitride/tantalum (TNT) layer. In another embodiment, the adhesion/barrier layer is a titanium nitride/titanium layer. In some embodiments, however, no adhesion/barrier layer is used in the methods or included in the metal interconnects provided herein. When no adhesion/barrier layer is used, a seed layer may be formed directly on a dielectric layer and, if present, a conductive region.

In one embodiment, an adhesion/barrier layer 120 is deposited in the dual damascene structure of FIG. 1A, as depicted at FIG. 1B. The adhesion/barrier layer 120 may be formed on a top surface 108 of the dielectric layer 102 as well as on the exposed top surface 118 of the substrate 106 (e.g., on conductive region 150). In the embodiment depicted at FIG. 1B, the adhesion/barrier layer 120 is also formed on the sidewalls 116 of the lower opening 114, and the sidewalls 112 of the upper opening 110.

### Seed Layer

The seed layers herein may include cobalt, a compound of formula (I), a compound of formula (II), or a combination thereof. The seed layers may be conformal layers. In one embodiment, the seed layers herein have a thickness less than 3 nm. For example, the seed layers may have a thickness of about 1 nm to about 3 nm. The seed layers may act as a nucleation layer for the growth of subsequent fill materials.

The seed layers herein generally may include any known seed layer material. The seed layers herein may include cobalt. For example, in one embodiment, the seed layer includes at least 50% cobalt by weight of the seed layer. In a particular embodiment, the seed layer includes about 90% to 100% cobalt by weight of the seed layer. Non-limiting examples of cobalt-based compound seed layers include cobalt silicide or cobalt germanide seed layers.

In one embodiment, a seed layer 130 that includes a compound of formula (I) and/or a compound of formula (II) is deposited in the dual damascene structure of FIG. 1B, as depicted at FIG. 1C. The seed layer 130 of FIG. 1C is deposited on the adhesion/barrier layer 120.

### Fill Material

The fill materials provided herein may include at least one of a compound of formula (I) or a compound of formula (II). Generally, any known fill materials may be used as the fill materials provided herein. For example, in one embodiment, the fill material may include at least 50% cobalt by weight, based on the weight of the fill material. In a particular embodiment, the fill material includes about 90% to 100% cobalt by weight of the fill material.

The fill materials provided herein may have a composition that differs from the composition of a seed layer. For example, a seed layer may include both silicon and cobalt, while a fill material may include only cobalt. In another example, a seed layer may include a first compound of formula (I) or formula (II), while a fill material may include a second compound of formula (I) or formula (II) that is different from the first compound of formula (I) or formula (II). A fill material also may have a different grain structure than a seed layer. For example, a seed layer may have a smaller grain structure than the grain structure of a fill material.

In one embodiment, a fill material 140 that includes cobalt or nickel is deposited in the dual damascene structure of FIG. 1C, as depicted at FIG. 1D. FIG. 1D depicts an embodiment in which the fill material 140 is deposited on the seed layer 130, such that the fill material 140 completely fills the openings (110, 114).

In embodiments, the fill material 140 may be formed by a process such as, but not limited to, CVD, ALD, PVD, electroplating, or electro-less plating. In one embodiment, the process method used to form the fill material 140 and the process used to form the seed layer 130 are different. Furthermore, the seed layer 130 may be formed conformally, while the fill material 140 may be formed in a non-conformal or bottom up approach. For example, the seed layer 130 may be formed by an ALD deposition process that forms a conformal layer on exposed surfaces of the barrier/adhesion layer 120 or substrate, while the fill material 140 may be formed by a PVD process that directionally sputters the fill material 140 onto the surfaces of the seed layer 130, with greater deposition rates on flat surfaces as opposed to on sidewall surfaces. In another example, the seed layer 130 may be formed by an ALD deposition process that forms a conformal layer on exposed surfaces of the receiving barrier/adhesion layer 120 or substrate, while the fill material 140 may be formed by an electroplating process that grows the fill material 140 from the surfaces of the seed layer 130. In yet another example, the seed layer 130 may be formed by a CVD deposition process and the fill material 140 may be formed by a PVD process.

In embodiments, the seed layer 130 and the fill material 140 are deposited by the same process (e.g., ALD, CVD, or PVD) but with different sets of deposition parameters, such as pressure, deposition rate, temperature, etc. For example, the seed layer 130 and the fill material 140 may be deposited by a CVD process; however, the set of parameters used in the CVD processing for the seed layer 130, such as deposition pressure and temperature, may be different than the set of parameters used in the CVD processing for the fill material 140. In another example, the seed layer 130 and the fill material 140 may be formed by a PVD process, but the seed layer 130 may be formed by a PVD process with a larger distance between the target and the receiving substrate than the PVD process used to form the fill material 140. In another embodiment, a metal fill material 140 may be formed by a colummated PVD process, while the seed layer 130 may be formed by a non-colummated PVD process. Alternatively, the seed layer may be formed by an ALD process with a lower deposition rate than the deposition rate of the ALD process used to form the fill material 140 such that the seed layer 130 may be formed more conformally than the fill material 140.

A cycling technique may be used to deposited the fill material 140 within the openings 114 and 110. One cycle may include one deposition of the fill material 140 and subsequent annealing. The annealing of one cycle may be performed at parameters (e.g., temperature and/or time) to facilitate reflow of a fill material to improve step coverage. The deposition operation of one cycle may be a short deposition to deposit less fill material, thereby requiring several operations to completely fill the via and line openings 114 and 110. In one embodiment, less than 5 cycles are required to dispose the fill material 140.

In one embodiment, an over burden 150 of fill material is deposited on the dual damascene structure 100 of FIG. 1D, as depicted at FIG. 1E. FIG. 1E depicts an embodiment in which the over burden 150 is deposited on the exposed surfaces of the seed layer 130. The over burden 150 may be formed by a process such as, but not limited to, CVD, ALD, PVD, electroplating, or electro-less plating.

A CMP process may be performed to remove the over burden 150, the fill material 140, the seed layer 140, and barrier/adhesion layer 120 deposited above the top surface 108 of the dielectric layer 102 of FIG. 1E, or the fill material 140, the seed layer 140, and barrier/adhesion layer 120 deposited above the top surface 108 of the dielectric layer 102 of FIG. 1D.

The CMP process may be a timed CMP process that is configured to stop at the top surface 108 of the line dielectric layer. In another embodiment, the CMP process may rely on the top surface 108 of the line dielectric layer as a stopping layer. Since it is believed that the thickness of the fill material deposited above a top surface of a line dielectric layer may vary, utilizing a top surface of a dielectric layer as a stopping layer may be a more reliable method. Alternatively or additionally, an etch process may be used to remove a barrier/adhesion layer, fill material, a seed layer, or a combination thereof deposited above a top surface of a dielectric layer.

### Annealing

An annealing process may optionally be performed. The annealing process may be performed after the depositing of an over burden. One or more annealing processes also may be performed as a fill material is deposited in a damascene or dual damascene structure as described herein.

The annealing may promote the growth of larger grain structures within a fill material, which may decrease resistivity, expel impurities from poor grain structures, or a combination thereof The annealing may include the use of a forming gas, including, but not limited to, nitrogen, hydrogen, argon, or a combination thereof. The annealing may be performed at a temperature less than the thermal budget of backend structures. For example, annealing may be performed at a temperature of about 300° C. to about 400° C. As another example, annealing may be performed at a temperature that is higher than the melting point of a fill material, but lower than the thermal budget of backend structures.

In one embodiment, the dual damascene structure 100 of FIG. 1E is subjected to annealing at a temperature of about 300° C. to about 400° C. for about 1 minute to about 1 hour followed by CMP, which results in the metal interconnect 101 depicted at FIG. 1F. Not wishing to be bound by any particular theory, it is believed that the annealing may drive the mixing of the compound of formula (I) and/or (II) of the seed layer 130 into the fully filled feature, as depicted at FIG. 1F. Not wishing to be bound by any particular theory, it is believed that a film of a compound of formula (I) and/or (II) may passivate a top surface of the trench, thereby preventing or reducing the likelihood of corrosion.

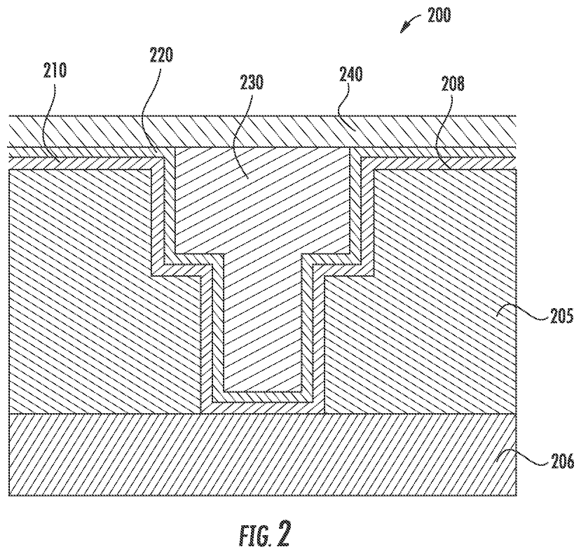

In embodiments, a seed layer and a fill material include a compound of formula (I) and/or formula (II). For example, FIG. 2 depicts a dual damascene structure 200 into which a barrier/adhesion layer 210, a seed layer 220 including a compound of formula (I) and/or formula (II), a fill material 230 including a compound of formula (I) and/or formula (II), and an over burden 240 of cobalt, nickel, or a combination thereof has been deposited. Therefore, the fill material 230 and the over burden 240 include different materials in the embodiment depicted at FIG. 2. The seed layer 220 and the fill material 230 may include different compounds of formula (I) and/or (II) or different combinations thereof. For example, the seed layer 220 and the fill material 230 may include [1] a compound of formula (I), [2] a compound of formula (II), or [3] a combination thereof. The seed layer 220 may include a compound of formula (I), and the fill material 230 may include a compound of formula (II), or vice versa. The dual damascene structure 200 of FIG. 2 may include a dielectric material 205 deposited on a substrate 206, and may include one or more of the additional features depicted at FIG. 1A. The dual damascene structure 200 of FIG. 2 may be subjected to annealing, which may drive the mixing of the compounds of formula (I) and/or (II). The structure then may be polished, such as by CMP. The polishing may remove the over burden and at least a portion of the barrier and/or adhesion layer, the seed layer, and/or the fill material deposited above the top surface 208 of the dielectric material 205. Not wishing to be bound by any particular theory, it is believed that a film of the compounds of formula (I) and/or (II) may passivate a top surface of the trench, thereby preventing or reducing the likelihood of corrosion.

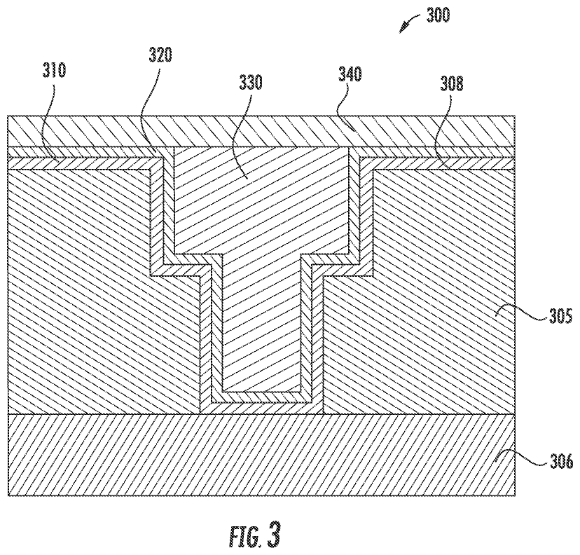

In embodiments, an over burden includes a compound of formula (I) and/or formula (II). For example, FIG. 3 depicts a dual damascene structure 300 into which a barrier/adhesion layer 310, a seed layer 320 of nickel, cobalt, or a combination thereof, a fill material 330 of cobalt, nickel, or a combination thereof, and an over burden 340 in which a compound of formula (I) and/or formula (II) is present. Therefore, the fill material 330 and the over burden 340 include different materials in the embodiment depicted at FIG. 3. The dual damascene structure 300 of FIG. 3 may include a dielectric material 305 deposited on a substrate 306, and may include one or more of the additional features depicted at FIG. 1A. The dual damascene structure 300 of FIG. 3 may be subjected to annealing, which may drive the mixing of the compounds of formula (I) and/or (II) into at least one of the fill material 330 or the seed layer 320. The structure then may be polished, such as by CMP. The polishing may remove the over burden and at least a portion of the barrier and/or adhesion layer, the seed layer, and/or the fill material deposited above the top surface 308 of the dielectric material 305. Not wishing to be bound by any particular theory, it is believed that a film of the compounds of formula (I) and/or (II) may passivate a top surface of the trench, thereby preventing or reducing the likelihood of corrosion.

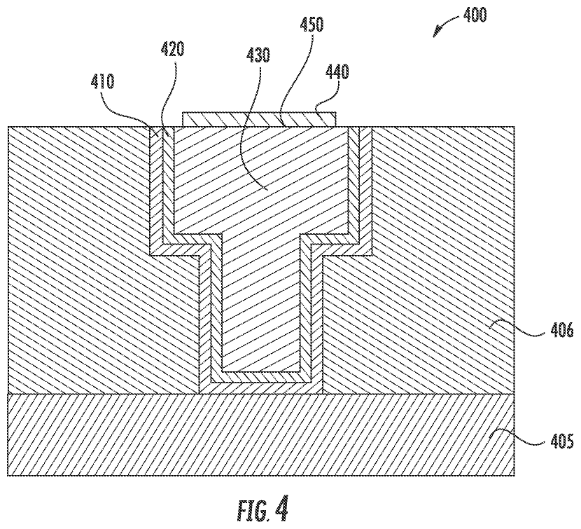

In embodiments, a cap including a compound of formula (I) and/or (II) is applied to a damascene or dual damascene structure. For example, FIG. 4 depicts an embodiment of a dual damascene structure 400 that includes a barrier/adhesion layer 410, a seed layer 420 of cobalt, nickel, or a combination thereof, a fill material 430 of cobalt, nickel, or a combination thereof, and a cap 440 including a compounds of formula (I) and/or (II) deposited on a top surface 450 of the fill material 430. The cap 440 may correspond to the dimensions of the top surface 450 of the fill material 430, thereby covering all or most of the top surface 450 of the fill material, as depicted at FIG. 4. The cap 440 also may cover at least a portion of the exposed surfaces of the seed layer 420, the barrier/adhesion layer 410, or a combination thereof The cap 440 may be applied after the fill material 440 is deposited in the dual damascene structure. The cap 440 may be applied after a CMP process is performed. The cap may be deposited using any known techniques, including those described herein, such as ALD, CVD, or electroless. In some embodiments, the cap is a “selective” cap that is deposited on the fill material 430, the exposed surfaces of at least one of the seed layer 420 and the barrier/adhesion layer 410, or a combination thereof, but the “selective” cap is not deposited on the dielectric material 406. In other embodiments, the cap is a “non-selective” cap applied by blanket deposition to a top surface of a damascene structure in a manner that may deposit a portion of the “non-selective” cap on the dielectric material 406. After its deposition, a “non-selective” cap may be annealed, and then removed by polishing. A “non-selective” cap may include a compound of formula (I) and/or (II). A “non-selective” cap also may include one or more elements (such as an element from which variables “Q” and “Z” herein may be selected), and, upon annealing, the one or more elements may combine with at least one of the fill material 430, seed layer 420, or barrier/adhesion layer 410. The annealing of the “non-selective” cap, therefore, may result in the formation of an alloy, including, but not limited to, an alloy according to formula (I) and/or (II).

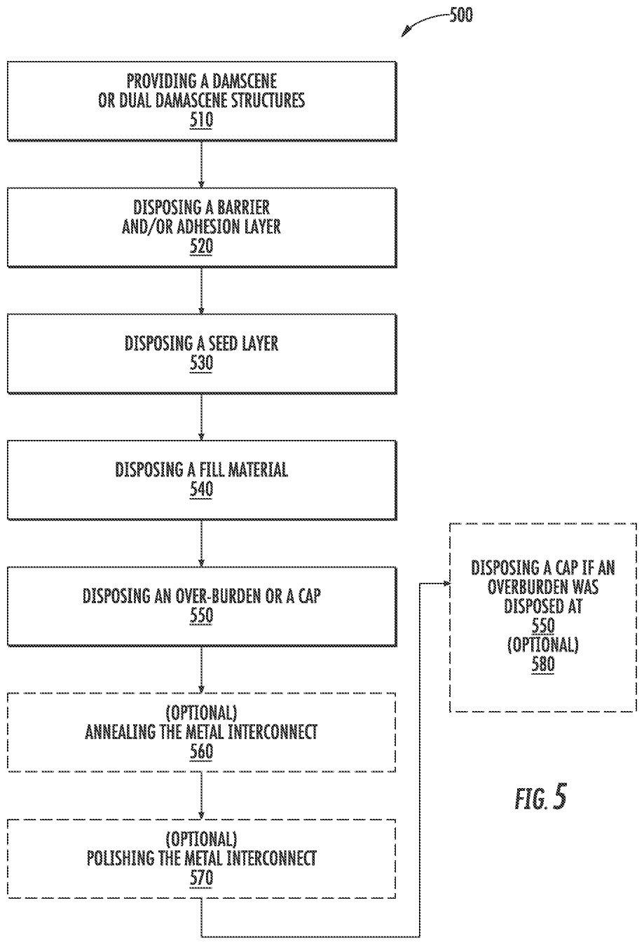

FIG. 5 is a flow chart 500 depicting an embodiment of a method of forming a metal interconnect, such as those depicted at FIG. 1, FIG. 2, FIG. 3, and FIG. 4. At 510, a damascene or dual damascene structure is provided. At 520, a barrier and/or adhesion layer is deposited in the damascene or dual damascene structure. In other embodiments, the methods provided herein do not include depositing a barrier and/or adhesion layer in the damascene or dual damascene structure. At 530, a seed layer is deposited on the barrier and/or adhesion layer. At 540, a fill material is deposited in the damascene or dual damascene structure and on the seed layer. At 550, an overburden or a cap is deposited on the fill material. At 560, the optional annealing of the metal interconnect is provided. At 570, the optional polishing of the metal interconnect, such as by CMP, is provided. At 580, the optional depositing of a cap is provided, which may be performed if an overburden was previously deposited on the structure and removed by polishing.

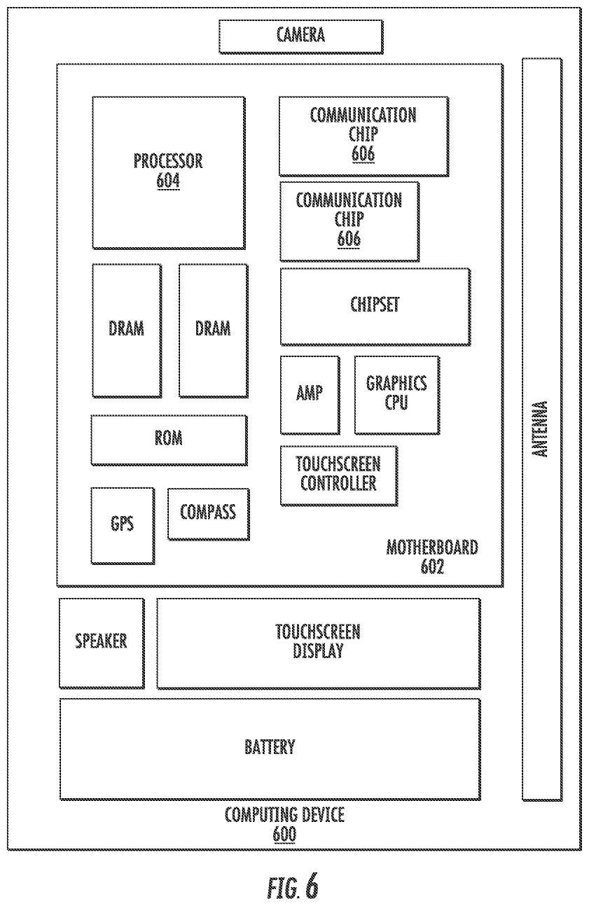

FIG. 6 illustrates a computing device 600 in accordance with one embodiment. The computing device 600 houses a board 602. The board 602 may include a number of components, including but not limited to a processor 604 and at least one communication chip 606. The processor 604 is physically and electrically coupled to the board 602. The at least one communication chip 606 may be physically and electrically coupled to the board 602. In further embodiments, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 602.11 family), WiMAX (IEEE 602.16 family), IEEE 602.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For example, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In embodiments, the integrated circuit die of the processor includes one or more metal or metal alloy interconnects as provided herein. The term “processor” may refer to any device or portion of a device that processes electronic data from registers and/or memory to transform that electronic data into other electronic data that may be stored in registers and/or memory.

The communication chip 606 also may include an integrated circuit die packaged within the communication chip 606. In embodiments, the integrated circuit die of the communication chip includes one or more metal or metal alloys interconnects as provided herein.

In embodiments, another component housed within the computing device 600 may contain an integrated circuit die that includes one or more metal interconnects provided herein.

The computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. The computing device 600 also may be any other electronic device that processes data.

### EXAMPLES

The following examples pertain to further embodiments. Various optional features of the apparatuses and methods described herein are provided by the Examples, and all optional features of the apparatuses may also be implemented with respect to the methods described herein. Specifics in the following examples may be used anywhere in one or more embodiments.

Example 1 is a metal interconnect comprising a compound according to formula (I) or formula (II)

CoₐQ_{q}Z_{z} (formula (I)),

Ni_{d}XₑY_{f} (formula (II));

wherein a, q, and z are weight percentages based on the total weight of the compound according to formula (I), a is about 50% to about 99.99%, q is about 0.01% to about 50%, and z is 0% to about 49.9%; Q, when z is 0%, is selected from Ni, Al, Mn, Si, Cr, V, Mo, Zr, Nb, Ta, or W; Q, when z is not 0%, is selected from Ni, Al, Mn, Si, Cr, V, Zr, Nb, or Ta, and Z is selected from Mo or W; wherein d, e, and f are weight percentages based on the total weight of the compound according to formula (II), d is about 50% to 100%, e is 0% to about 50%, f is 0% to about 49.99%; X, when f is 0%, is selected from Co, Al, Mn, Si, Cr, V, Mo, Zr, Nb, Ta, or W; X, when f is not 0%, is selected from Co, Al, Mn, Si, Cr, V, Zr, Nb, or Ta, and Y is selected from Mo or W.

In Example 2, the subject matter of Example 1 can optionally include the compound according to formula (I), wherein Q is Ni, a is about 80% to about 95%, q is about 5% to about 20%, and z is 0%.

In Example 3, the subject matter of Example 1 can optionally include the compound according to formula (I), wherein Q is Ni, a is about 84% to about 88%, q is about 12% to about 16%, and z is 0%.

In Example 4, the subject matter of Example 1 can optionally include the compound according to formula (I), wherein Q is Ni, a is about 86%, q is about 14%, and z is 0%.

In Example 5, the subject matter of Example 1 can optionally include the compound according to formula (I), wherein Q is Ni, a is about 96% to about 99%, q is about 1% to about 4%, and z is 0%.

In Example 6, the subject matter of Example 1 can optionally include the compound according to formula (I), wherein Q is Ni, a is about 97%, q is about 3%, and z is 0%.

In Example 7, the subject matter of Example 1 can optionally include the compound according to formula (I), wherein Q is Si, and z is 0%.

In Example 8, the subject matter of Examples 1-7 can optionally include the compound according to formula (II), wherein e and f are 0%.

Example 9 is a metal interconnect comprising (1) a compound according to formula (I) or formula (II)

CoₐQ_{q}Z_{z} (formula (I)),

Ni_{d}XₑY_{f} (formula (II)); and

(2) two or more of the following materials or layers—(i) a barrier and/or adhesion layer, (ii) a seed layer, (iii) a fill material, and (iv) a cap, wherein the compound according to formula (I) or formula (II) is present in at least one of the barrier and/or adhesion layer, the seed layer, the fill material, or the cap; wherein a, q, and z are weight percentages based on the total weight of the compound according to formula (I), a is about 50% to about 99.99%, q is about 0.01% to about 50%, and z is 0% to about 49.9%; Q, when z is 0%, is selected from Ni, Al, Mn, Si, Cr, V, Mo, Zr, Nb, Ta, or W; Q, when z is not 0%, is selected from Ni, Al, Mn, Si, Cr, V, Zr, Nb, or Ta, and Z is selected from Mo or W; wherein d, e, and f are weight percentages based on the total weight of the compound according to formula (II), d is about 50% to 100%, e is 0% to about 50%, f is 0% to about 49.99%; X, when f is 0%, is selected from Co, Al, Mn, Si, Cr, V, Mo, Zr, Nb, Ta, or W; X, when f is not 0%, is selected from Co, Al, Mn, Si, Cr, V, Zr, Nb, or Ta, and Y is selected from Mo or W.

In Example 10, the subject matter of Example 9 can optionally include the barrier and/or adhesion layer.

In Example 11, the subject matter of Examples 9-10 can optionally include the seed layer.

In Example 12, the subject matter of Examples 9-11 can optionally include the fill material.

In Example 13, the subject matter of Examples 9-12 can optionally include the cap.

In Example 14, the subject matter of Examples 9-13 can optionally include the compound according to formula (I), wherein Q is Ni, a is about 80% to about 95%, q is about 5% to about 20%, and z is 0%.

In Example 15, the subject matter of Examples 9-13 can optionally include the compound according to formula (I), wherein Q is Ni, a is about 84% to about 88%, q is about 12% to about 16%, and z is 0%.

In Example 16, the subject matter of Examples 9-13 can optionally include the compound according to formula (I), wherein Q is Ni, a is about 86%, q is about 14%, and z is 0%.

In Example 17, the subject matter of Examples 9-13 can optionally include the compound according to formula (I), wherein Q is Ni, a is about 96% to about 99%, q is about 1% to about 4%, and z is 0%.

In Example 18, the subject matter of Examples 9-13 can optionally include the compound according to formula (I), wherein Q is Ni, a is about 97%, q is about 3%, and z is 0%.

In Example 19, the subject matter of Examples 9-13 can optionally include the compound according to formula (I), wherein Q is Si, and z is 0%.

In Example 20, the subject matter of Examples 9-19 can optionally include the compound according to formula (II), wherein e and f are 0%.

Example 21 is a method of forming a metal interconnect comprising providing a damascene or a dual damascene structure; depositing a barrier and/or adhesion layer on the damascene or the dual damascene structure; depositing a seed layer on the barrier and/or adhesion layer; depositing a fill material in the damascene or the dual damascene structure; and depositing (i) an over burden, or (ii) a cap on the fill material; wherein at least one of the barrier and/or adhesion layer, the seed layer, the fill material, the over burden, or the cap comprises a compound according to formula (I) or formula (II)

CoₐQ_{q}Z_{z} (formula (I)),

Ni_{d}XₑY_{f} (formula (II));

wherein a, q, and z are weight percentages based on the total weight of the compound according to formula (I), a is about 50% to about 99.99%, q is about 0.01% to about 50%, and z is 0% to about 49.9%; Q, when z is 0%, is selected from Ni, Al, Mn, Si, Cr, V, Mo, Zr, Nb, Ta, or W; Q, when z is not 0%, is selected from Ni, Al, Mn, Si, Cr, V, Zr, Nb, or Ta, and Z is selected from Mo or W; wherein d, e, and f are weight percentages based on the total weight of the compound according to formula (II), d is about 50% to 100%, e is 0% to about 50%, f is 0% to about 49.99%; X, when f is 0%, is selected from Co, Al, Mn, Si, Cr, V, Mo, Zr, Nb, Ta, or W; X, when f is not 0%, is selected from Co, Al, Mn, Si, Cr, V, Zr, Nb, or Ta, and Y is selected from Mo or W.

In Example 22, the subject matter of Example 21 can optionally include annealing the metal interconnect.

In Example 23, the subject matter of Examples 21-22 can optionally include polishing the metal interconnect.

In Example 24, the subject matter of Example 23 can optionally include chemical mechanical planarization (CMP).

In Example 25, the subject matter of Examples 21-24 can optionally include the seed layer comprising the compound according to formula (I) or formula (II).

In Example 26, the subject matter of Examples 21-24 can optionally include the seed layer and the fill material comprising the compound according to formula (I) or formula (II).

In Example 27, the subject matter of Examples 21-26 can optionally include the over burden comprising the compound according to formula (I) or formula (II).

In Example 28, the subject matter of Examples 21-27 can optionally include the cap comprising the compound according to formula (I) or formula (II).

In Example 29, the subject matter of Examples 21-28 can optionally include a dual damascene structure comprising a dielectric layer deposited on a substrate, the substrate comprising a conductive region; and an opening in the dielectric layer exposing the conductive region of the substrate, the opening having a lower portion and an upper portion, wherein the upper portion is wider than the lower portion.

Example 30 is a computing device comprising a processor comprising a metal interconnect, wherein the metal interconnect comprises a compound according to formula (I) or formula (II)

CoₐQ_{q}Z_{z} (formula (I)),

Ni_{d}XₑY_{f} (formula (II));

wherein a, q, and z are weight percentages based on the total weight of the compound according to formula (I), a is about 50% to about 99.99%, q is about 0.01% to about 50%, and z is 0% to about 49.9%; Q, when z is 0%, is selected from Ni, Al, Mn, Si, Cr, V, Mo, Zr, Nb, Ta, or W; Q, when z is not 0%, is selected from Ni, Al, Mn, Si, Cr, V, Zr, Nb, or Ta, and Z is selected from Mo or W; wherein d, e, and f are weight percentages based on the total weight of the compound according to formula (II), d is about 50% to 100%, e is 0% to about 50%, f is 0% to about 49.99%; X, when f is 0%, is selected from Co, Al, Mn, Si, Cr, V, Mo, Zr, Nb, Ta, or W; X, when f is not 0%, is selected from Co, Al, Mn, Si, Cr, V, Zr, Nb, or Ta, and Y is selected from Mo or W.

In Example 31, the subject matter of Example 30 can optionally include a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder.

In Example 32, the subject matter of Examples 30-31 can optionally include the compound according to formula (I), wherein Q is Ni, a is about 80% to about 95%, q is about 5% to about 20%, and z is 0%.

In Example 33, the subject matter of Examples 30-31 can optionally include the compound according to formula (I), wherein Q is Ni, a is about 84% to about 88%, q is about 12% to about 16%, and z is 0%.

In Example 34, the subject matter of Examples 30-31 can optionally include the compound according to formula (I), wherein Q is Ni, a is about 86%, q is about 14%, and z is 0%.

In Example 35, the subject matter of Examples 30-31 can optionally include the compound according to formula (I), wherein Q is Ni, a is about 96% to about 99%, q is about 1% to about 4%, and z is 0%.

In Example 36, the subject matter of Examples 30-31 can optionally include the compound according to formula (I), wherein Q is Ni, a is about 97%, q is about 3%, and z is 0%.

In Example 37, the subject matter of Examples 30-31 can optionally include the compound according to formula (I), wherein Q is Si, and z is 0%.

In Example 38, the subject matter of Examples 30-31 can optionally include the compound according to formula (II), wherein e and f are 0%.

In the descriptions provided herein, the terms “includes,” “is,” “containing,” “having,” and “comprises” are used in an open-ended fashion, and thus should be interpreted to mean “including, but not limited to.” When methods and metal interconnects are claimed or described in terms of “comprising” various components or processing features, the composite materials and methods can also “consist essentially of” or “consist of” the various components or processing features, unless stated otherwise.

The terms “a,” “an,” and “the” are intended to include plural alternatives, e.g., at least one. For instance, the disclosure of “a compound,” “a seed layer,” “a cap”, and the like, is meant to encompass one, or mixtures or combinations of more than one compound, seed layer, cap, and the like, unless otherwise specified.

Various numerical ranges may be disclosed herein. When Applicant discloses or claims a range of any type, Applicant's intent is to disclose or claim individually each possible number that such a range could reasonably encompass, including end points of the range as well as any sub-ranges and combinations of sub-ranges encompassed therein, unless otherwise specified. Moreover, all numerical end points of ranges disclosed herein are approximate. As a representative example, Applicant discloses, in one embodiment, that “a is about 80% to about 95%.” This range should be interpreted as encompassing values of “a” in a range of about 80% to about 95%, and further encompasses “about” each of 81%, 82%, 83%, 84%, 85%, 86%, 87%, 88%, 89%, 90%, 91%, 92%, 93%, and 94%, including any ranges and sub-ranges between any of these values.

The processes described and shown above may be carried out or performed in any suitable order as desired in various implementations. Additionally, in certain implementations, at least a portion of the processes may be carried out in parallel. Furthermore, in certain implementations, less than or more than the processes described may be performed.

Certain aspects of the disclosure are described above with reference to flow diagrams of methods or apparatuses according to various implementations. Some blocks of the flow diagrams may not necessarily need to be performed in the order presented, or may not necessarily need to be performed at all, according to some implementations.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims.

1-20. (canceled)

21. An integrated circuit (IC) interconnect, comprising a compound of CoₐQ_{q}Z_{z} or Ni_{d}XₑY_{f},
wherein a, q, and z are weight percentages based on the total weight of the compound, a is 50% to 99.99%, q is 0.01% to 50%, and z is 0% to 49.9%;
wherein Q, when z is 0%, is Ni, Al, Mn, Si, Cr, V, Mo, Zr, Nb, Ta, or W; and
wherein Q, when z is not 0%, is Ni, Al, Mn, Si, Cr, V, Zr, Nb, or Ta, and Z is Mo or W; and
wherein d, e, and f are weight percentages based on the total weight of the compound, d is 50% to 100%, e is 0% to 50%, f is 0% to 49.99%;
wherein X, when f is 0%, is Co, Al, Mn, Si, Cr, V, Mo, Zr, Nb, Ta, or W; and
wherein X, when f is not 0%, is Co, Al, Mn, Si, Cr, V, Zr, Nb, or Ta, and Y is Mo or W.

22. The IC interconnect of claim 21, further comprising two or more of the following: (i) a barrier or adhesion layer, (ii) a seed layer, (iii) a fill material, or (iv) a cap, wherein least one of the barrier or adhesion layer, the seed layer, the fill material, or the cap comprises the compound.

23. The IC interconnect of one of claim 21, wherein the compound is CoₐQ_{q}Z_{z}, and wherein Q is Ni, a is 80% to 95%, q is 5% to 20%, and z is 0%.

24. The IC interconnect of claim 23, wherein: a is 84% to 88%; q is 12% to 16%; and z is 0%.

25. The IC interconnect of claim 24, wherein a is 86%; q is 14%, and z is 0%.

26. The IC interconnect of claim 21, wherein the compound is CoₐQ_{q}Z_{z}, and wherein Q is Ni, a is 96% to 99%, q is 1% to 4%, and z is 0%.

27. The IC interconnect of claim 26, wherein: a is 97%; q is 3%; and z is 0%.

28. The IC interconnect of one of claim 21, wherein the metal interconnect comprises the compound according to formula (I), wherein Q is Si, and z is 0%.

29. The IC interconnect of claim 21, wherein the metal interconnect comprises Ni_{d}XₑY_{f}, and wherein e and f are 0%.

30. A method of forming an integrated circuit (IC) interconnect, the method comprising:
receiving a damascene or a dual damascene structure;
depositing a barrier or adhesion layer on the damascene or the dual damascene structure;
depositing a seed layer on the barrier or adhesion layer;
depositing a fill material in the damascene or the dual damascene structure; and
depositing (i) an over burden, or (ii) a cap on the fill material;
wherein at least one of the barrier or adhesion layer, the seed layer, the fill material, the over burden, or the cap comprisies a compound of CoₐQ_{q}Z_{z} or Ni_{d}XₑY_{f};
wherein a, q, and z are weight percentages based on the total weight of the compound, a is 50% to 99.99%, q is 0.01% to 50%, and z is 0% to 49.9%;
wherein Q, when z is 0%, is Ni, Al, Mn, Si, Cr, V, Mo, Zr, Nb, Ta, or W, and
wherein Q, when z is not 0%, is Ni, Al, Mn, Si, Cr, V, Zr, Nb, or Ta, and Z is Mo or W; and
wherein d, e, and f are weight percentages based on the total weight of the compound, d is 50% to 100%, e is 0% to 50%, f is 0% to 49.99%;
wherein X, when f is 0%, is Co, Al, Mn, Si, Cr, V, Mo, Zr, Nb, Ta, or W, and
wherein X, when f is not 0%, is Co, Al, Mn, Si, Cr, V, Zr, Nb, or Ta, and Y is Mo or W.

31. The method of claim 30, further comprising annealing the metal interconnect.

32. The method of claim 30, further comprising polishing the metal interconnect.

33. The method of claim 32, wherein the polishing comprises chemical mechanical planarization (CMP).

34. The method of claim 30, wherein the seed layer comprises the compound.

35. The method of claim 30, wherein the seed layer and the fill material comprise the compound.

36. The method of claim 30, wherein the over burden comprises the compound.

37. The method of claim 30, wherein the cap comprises the compound.

38. The method of claim 30, wherein the dual damascene structure comprises:
a dielectric layer over a substrate, the substrate comprising a conductive region; and
an opening through the dielectric layer and intersecting the conductive region of the substrate, the opening having a lower portion and an upper portion, wherein the upper portion is wider than the lower portion.

39. A computing device, comprising a processor comprising the IC interconnect of claim 21.

40. The computing device of claim 39, wherein the computing device is a laptop, a smartphone, a tablet, a personal digital assistant (PDA), a desktop computer, a server, a set-top box, an entertainment control unit, a digital camera, a portable music player, or a digital video recorder.
